(19) United States
(12) Patent Application Publication
(10) Pub. No.: US 2019/0221330 A1
(43) Pub. Date: Jul. 18, 2019

(54) ELECTRIC CABLE HAVING A COOLANT LINE

(71) Applicant: PHOENIX CONTACT E-MOBILITY GMBH, Schieder-Schwalenberg (DE)

(72) Inventor: Thomas Fuehrer, Blomberg (DE)

(21) Appl. No.: 16/334,752

(22) PCT Filed: Sep. 26, 2017
(86) PCT No.: PCT/EP2017/074272

§ 371 Date: Mar. 20, 2019

(30) Foreign Application Priority Data
Sep. 27, 2016 (DE) 10 2016 118 193.5

(51) Int. Cl. H01B 7/42; G01R 27/16

(52) U.S. Cl. CPC H01B 7/423; B60L 53/18; G01R 27/16

(57) ABSTRACT

A cable for transferring an electric current includes: a cable sleeve; at least one electrical load line, extending into the cable sleeve, for conducting the electric current; at least one cooling line, extending into the cable sleeve, for conducting a coolant; and at least one electrically-conductive sensing line, which extends into the cable sleeve and, at least in sections, is not electrically insulated, for detecting a measurement signal indicating a change in an electrical conductivity in the cable sleeve.

### CROSS-REFERENCE TO PRIOR APPLICATIONS

This application is a U.S. National Phase application under 35 U.S.C. § 371 of International Application No. PCT/EP2017/074272, filed on Sep. 26, 2017, and claims benefit to German Patent Application No. DE 10 2016 118 193.5, filed on Sep. 27, 2016. The International Application was published in German on Apr. 5, 2018 as WO 2018/060152 under PCT Article 21(2).

### FIELD

The invention relates to a cable for transferring an electric current.

### BACKGROUND

Such a cable comprises a cable sleeve, at least one electrical load line, extending into the cable sleeve, for conducting an electric current, and at least one cooling line, extending into the cable sleeve, for conducting a coolant.

Such a cable may be used, in particular, as a charging cable for charging an electrically-powered vehicle (also referred to as an electric vehicle). In such a case, the cable may, for example, be connected to a charging station, on the one hand, and carry a connector part in the form of a charging plug, on the other, which connector part can be plugged into an associated mating connector part in the form of a charging socket on a vehicle, in order to establish an electrical connection between the charging station and the vehicle in this manner.

In principle, charging currents can be transferred as direct currents or as alternating currents, wherein charging currents in the form of direct current, in particular, have a high current strength, e.g., greater than 200 A or even greater than 350 A, and can lead to the heating of both the cable and a connector part connected to the cable. This may require that the cable be cooled.

One solution for counteracting such heating of the cable could be to further enlarge the cross-section of the load line in the cable. However, this has the disadvantage that, as a whole, the cable becomes heavier and less flexible, which can affect the ability of a user to handle the cable.

A charging cable known from DE 10 2010 007 975 B4 features a cooling line that comprises a supply line and a return line for a coolant, thus allowing coolant to flow in and out of the charging cable. The cooling line of DE 10 2010 007 975 B4 serves the purpose of, for one, dissipating the heat generated by an energy accumulator in a vehicle, but also cooling the cable itself

With a cable known from DE 10 2011 100 389 A1 in the form of a charging cable for charging an electric vehicle, a cooling line is laid in a cable sleeve, providing a forward and a return flow for a coolant in order to absorb heat at the cable and dissipate it from the cable.

With a power cable known from DE 42 08 928 C1 in the form of a single or multi-conductor composite cable, hollow channels in which a coolant can be fed are provided. In a parallel channel, a communication cable or a sensor, for example—e.g., in the form of a fiber optic cable—can also be provided for detecting heating.

With a cable in the form of a charging cable that has one or more cooling lines, damage may occur if the cable is bent or if a vehicle drives over the cable. If a cooling line is damaged in this manner, coolant, e.g., water, can leak out from the cooling line and enter the interior of the cable sleeve. As there may generally be intermediate spaces in the cable sleeve, coolant may spread in this manner in the cable sleeve and, for example, flow to a connector part connected to the charging cable or to a charging device connected to the charging cable, which may be dangerous because high-voltage components are present on a connector part and on a charging device, the insulation of which may be endangered by uncontrolled access of an electrically-conductive coolant—for example, water.

### SUMMARY

In an embodiment, the present invention provides a cable for transferring an electric current, comprising: a cable sleeve; at least one electrical load line, extending into the cable sleeve, configured to conduct the electric current; at least one cooling line, extending into the cable sleeve, configured to conduct a coolant; and at least one electrically-conductive sensing line, which extends into the cable sleeve and, at least in sections, is not electrically insulated, configured to detect a measurement signal indicating a change in an electrical conductivity in the cable sleeve.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 a view of a charging station with a cable arranged thereon;

FIG. 2 a view of a connector part of the cable;

FIG. 3 a view of an embodiment of a cable in the form of a charging cable;

FIG. 4 a cross-sectional view of the cable;

FIG. 5 a schematic view of the cable, with sensing lines extended thereinto;

FIG. 6 a schematic view of the cable and the sensing lines extending thereinto, when a coolant leaks out of a cooling line; and

FIG. 7 a schematic view of an additional embodiment of a cable, with sensing lines extended thereinto.

### DETAILED DESCRIPTION

In an embodiment, the present invention provides a cable for conducting an electric current, by means of which an operational hazard, in the event of coolant leaking out of the cooling line extended into the cable sleeve, can at least be reduced.

Accordingly, the cable comprises at least one electrically-conductive sensing line, which extends into the cable sleeve and, at least in sections, is not electrically insulated, for detecting a measurement signal indicating a change in the electrical conductivity in the cable sleeve.

Accordingly, a sensing line is to be laid in the cable sleeve, through which a measurement signal can be picked up, which measurement signal indicates a change in the electrical conductivity properties in the cable sleeve. If a coolant that is electrically conductive at least to a limited extent, e.g., water, leaks out of a cooling line, the electrical conductivity changes, at least in those areas into which the coolant flows. The sensing line, which is not electrically insulated, at least in sections, can come into electrical contact with the coolant, which enables a measurement signal to be picked up via the sensing line, e.g., by measuring a current when a voltage is applied, which allows conclusions to be drawn regarding a change in the electrical conductivity in the cable sleeve, and thus regarding the possible leakage of a coolant in the cable sleeve.

For example, a first sensing line and a second sensing line spaced from the first sensing line can be laid in the cable sleeve. A voltage difference can be applied between these sensing lines in order to draw conclusions, by measuring an electric current, regarding a coolant leaking out in the cable sleeve. If the cooling lines are intact and no coolant has leaked out, the sensing lines are electrically insulated from each other. If coolant has leaked out, the coolant can, at least in areas, bridge the electrical insulation between the sensing lines in the cable sleeve, which can be detected by the measurement signal picked up via the sensing lines.

At this point, it should be noted that, basically, one sensing line can be sufficient. For example, a measurement signal can be picked up via a measuring potential applied to a sensing line and via a shielded conductor at ground potential, which indicates a change in the electrical conductivity in the cable sleeve.

If two sensing lines are laid in the cable sleeve, such lines are arranged at a distance from each other and are not in electrical contact with each other. The sensing lines are thus electrically insulated from each other if the cooling lines are functional and not damaged, and thus no (electrically-conductive) coolant has leaked out of the cooling lines. If coolant has leaked out, the electrical insulation between the sensing lines can thereby be bridged in certain areas, which can be detected, for example, on the basis of a current flow, with voltage applied between the sensing lines.

The sensing lines do not necessarily lack electrical insulation along their entire length; thus, they do not have an electrically-insulating sheath. It can be sufficient if the sensing lines are electrically exposed only in sections. In such areas, which are enveloped by an electrical sheath and thus insulated, the sensing lines can also be in contact with each other. The decisive factor is only that sensing lines not be in contact with electrically non-insulated sections, and that the sensing lines be electrically insulated from each other.

In one specific design, into the cable, a central, first cooling line extends through which, for example, an inflow of a coolant can be provided. One or more second cooling lines and also one or more electrical load lines can be grouped around this cooling line, which extends centrally within the cable sleeve, such that the second cooling lines and the load lines accommodate the central, first cooling line between them. The second cooling lines can be used, for example, to provide a return flow for the coolant.

If the cable is designed as a charging cable for charging an electric vehicle, an inflow can be provided, via the central, first cooling line, to a connector part arranged on the cable, for example. However, via the second cooling lines, the coolant can flow back from the mating connector part to a charging station, in order to dissipate heat from the cable and the connector part.

The at least one sensing line preferably extends into an intermediate space between the central, first cooling line and the at least one second cooling line and/or the at least one electrical load line. The central, first cooling line and also the second cooling lines and the load lines have a shape that is at least approximately circular in cross-section. This results in intermediate spaces between the central, first cooling line, the second cooling lines, and the load lines, into which one or more sensing lines can be extended.

At this point, it should be noted that more than two sensing lines can also be laid in the cable sleeve. For example, into each intermediate space between the central, first cooling line, the second cooling lines, and the load lines, a sensing line can be extended, such that a spatially close detection of any leakage of coolant becomes possible. A measuring potential and a ground potential can be alternately applied to the sensing lines such that a potential difference arises between adjacent sensing lines.

The at least one sensing line is preferably connected to a control device, which is designed to apply a measuring potential to the at least one sensing line, in order to detect a measurement signal indicating a change in the conductivity in the cable sleeve. If the cable is designed as a charging cable for charging an electric vehicle, the control device may, for example, be integrated into a charging station to which the cable is connected. For example, the control device can be used to apply a voltage between a first sensing line and a second sensing line, in order to detect a current flow across the sensing lines on the basis of the voltage, and to deduce from this the electrical conductivity properties in the cable sleeve.

Through the control device, the control of a load current flowing over the load line can be provided. For example, the control device may be designed to switch off a current flowing over the load line if an (impermissible) change in conductivity is detected in the cable sleeve. If the cable is designed as a charging cable for charging an electric vehicle, a charging process can, via the control device, be interrupted or not started at all, if damage to a cooling line is detected on the basis of a change in the conductivity in the cable sleeve.

The cable is preferably a component of a charging system for charging an electric vehicle and is connected at a first end to a connector part, e.g., a charging plug, and at its other, second end to a charging station for charging an electric vehicle. The cable sleeve is preferably flexible, such that the cable can be laid from the charging station to an electric vehicle in a flexible manner.

FIG. 1 shows a charging station 1 used to charge an electrically-powered vehicle 4, also referred to as an electric vehicle. The charging station 1 is designed to provide a charging current in the form of an alternating current or a direct current, and has a cable 2 connected at one end 201 to charging station 1 and, at another end 200, to a connector part 3 in the form of a charging plug.

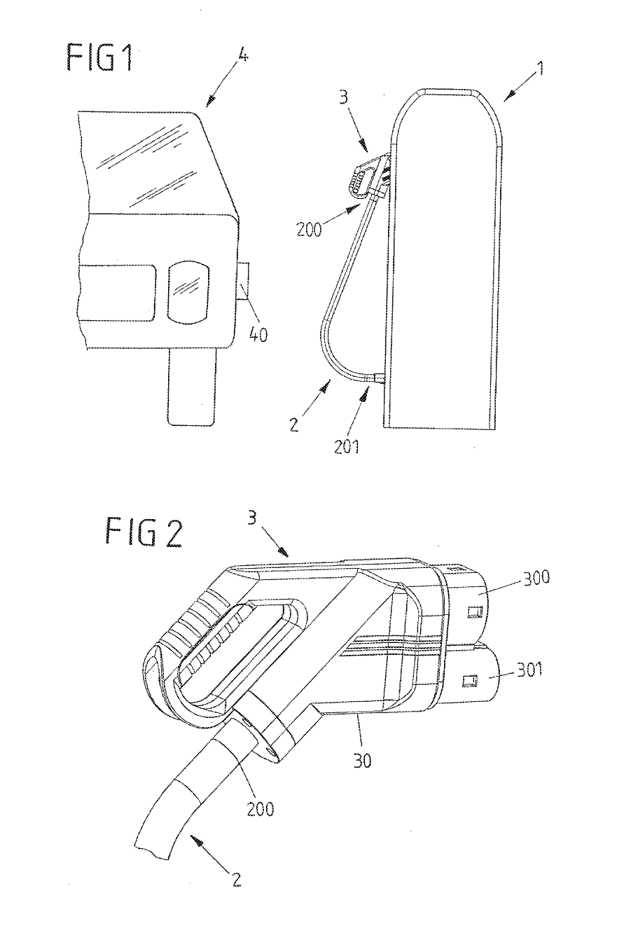

As can be seen from the enlarged view according to FIG. 2, the connector part 3 on a housing 30 has plug-in sections 300, 301, with which the connector part 3 can be engaged in a plugged manner with an associated mating connector part 40 in the form of a charging socket on the vehicle 4. In this manner, the charging station 1 can be electrically connected to the vehicle 4, in order to transfer charging currents from the charging station 1 to the vehicle 4.

In order to enable the electric vehicle 4 to be charged rapidly, the transferred charging currents have a large current strength, e.g., greater than 200 A—possibly, even on the order of 350 A or higher. Due to such high charging currents, thermal losses occur on the lines of the cable 2, which can lead to the heating of the cable 2. For example, at the current strengths used at a charging station 1 today, thermal losses can occur in the range of 150 W per meter of the cable 2, or even greater, which can be accompanied by a considerable heating of the cable 2.

In general, a large current strength could be countered by using electrical lines with a large line cross-section. However, this not only increases the costs of the cable 2, but also impairs the ability to handle the cable 2, because the line cross-section also increases the weight of the cables and thus of the cable 2. As such, there is a need for an active cooling of the cable 2 to prevent excessive heating of the cable 2, without necessarily requiring an excessive enlargement of the line cross-section of the lines laid in the cable 2.

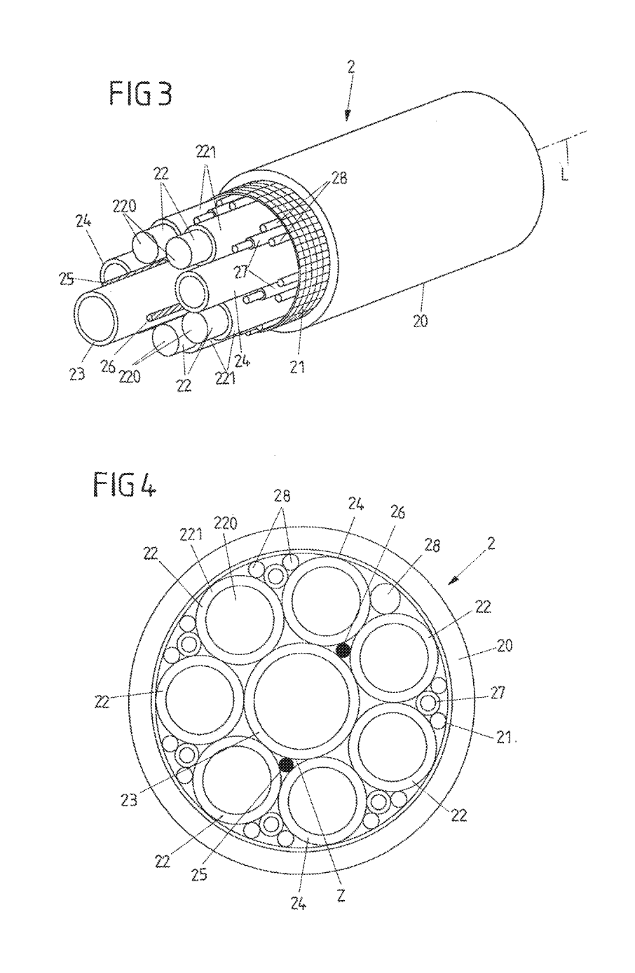

With one embodiment of a cable 2 shown in FIG. 3, cooling lines 23, 24 are therefore laid in a cable sleeve 20; these provide a coolant flow within the cable 2, and in this manner can absorb and dissipate heat on the load lines 22 extended into the cable sleeve 20.

As can be seen in FIG. 3 and the cross-sectional view according to FIG. 4, the cable 2 has an outer cable sleeve 20 made of an electrically-insulating, flexible material, on the inside of which a shield line 21 is arranged. The shield line 21 is located at an electrical ground potential and serves for the electromagnetic shielding of the load lines 22 extending into the cable sleeve 20 towards the outside.

A number of load lines 22 are laid inside the cable conduit 20; these can be used to transfer an alternating current or a direct current and are connected on the side of the connector part 3 to contact elements at the plug-in sections 300, 301. Each load line 22 has an electrically-conductive line core 220 that is enveloped in an electrically-insulating sheath 221. Load currents are transferred via the load lines 22 to the connector part 3, such that, when the connector part 3 is connected to the charging socket 40 on the side of the electric vehicle, charging currents can be transferred to charge the electric vehicle 4.

As can be seen in particular from the cross-sectional view according to FIG. 4, the cable 2 has a central, first cooling line 23, which, for example, provides an inflow of coolant up to the connector part 3. The load lines 22 and two second cooling lines 24 are grouped around the central, first cooling line 23; through these, for example, a return flow of the coolant from the connector part 3 back to the charging station 1 can be provided. In addition, signal lines 27 are enclosed in the cable sleeve 20; these can be used to transfer control signals from the charging station 1 to the connector part 3 and vice versa. Filling elements 28 are used to fill the interior of the cable sleeve 20 in such a way that the cable sleeve 20, in cross-section, takes a shape that is at least approximately circular, as can be seen in FIG. 4.

The cable 2 is extended along a longitudinal axis L, but can be bent flexibly. The central, first cooling line 23 is coaxial to the longitudinal axis L. The load lines 22 and the second cooling lines 24 are distributed circumferentially around the longitudinal axis L on the central, first cooling line 23.

Each of the central, first cooling line 23, the second cooling lines 24, and the load lines 22 has a shape that is at least approximately circular in cross-section, as can be seen in FIG. 4. This results in intermediate spaces Z between the central, first cooling line 23, the second cooling lines 24, and the load lines 22. In these intermediate spaces Z, for the embodiments according to FIGS. 3 and 4, two sensing lines 25, 26 are laid; these extend longitudinally inside the cable sleeve 20 and are each in contact with the central cooling line 23, one of the second cooling lines 24, and a load line 22. The sensing lines 25, 26, at least in sections, are not electrically insulated - preferably, along their entire length within the cable sleeve 20. Thus, the electrically-conductive conductors of the sensing lines 25, 26 are free within the cable sleeve 20, but are spaced apart from each other and not electrically connected to each other, such that the sensing lines 25, 26 are electrically insulated from each other in a normal state of use of the cable 2.

As shown schematically in FIG. 5, the sensing lines 25, 26 are connected on the side of charging station 1 to a control device 10. Sensing lines 25, 26 can be used to detect if there is a change in the electrical conductivity within the cable sleeve 20 due to coolant leaking from one of the cooling lines 23, 24—for example, if one of the cooling lines 23, 24 is damaged.

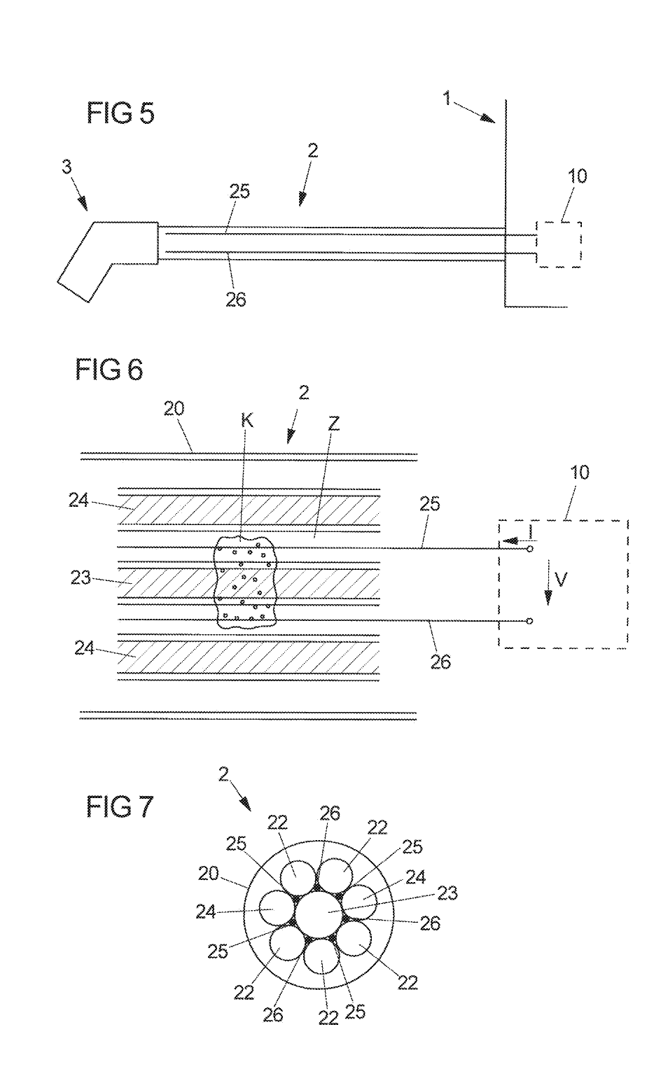

If one of the cooling lines 23, 24 is damaged, as shown schematically in FIG. 6, coolant K can leak out of the respective cooling line 23, 24 and enter the interior of the cable sleeve 20—in particular, into the intermediate spaces Z between the lines 22-24 extended into the cable sleeve 20. If the coolant K is electrically conductive at least to a limited extent (as is the case with water, for example), the electrical insulation between the sensing lines 25, 26 is bridged locally via the coolant K, such that, if a voltage difference V is applied between the sensing lines 25, 26, a current flow I via the sensing lines 25, 26 arises, which can be evaluated on the part of the control device 10. Thus, a current flow can be used to detect an impairment of the insulation between sensing lines 25, 26, in order to, in this manner, close a leak in one of the cooling lines 23, 24.

In doing so, the control device 10 can be designed, for example, to control the current flow via the load lines 22, if a change in conductivity is detected within the cable sleeve 20. For example, a load current can be switched off in order to terminate a charging process in such manner, if an (impermissible) change in the electrical conductivity properties within the cable sleeve 20 is detected.

With the embodiment according to FIGS. 3 and 4, there are two sensing lines 25, 26 to which a voltage difference V is applied during operation via the control device 10, in order to, on the basis of a current flow via the sensing lines 25, 26, close a leak in one of the cooling lines 23, 24. For example, a measuring potential can be applied to a first sensing line 25, while the other sensing line 26 is at ground potential. If a current flow I arises, this indicates a bridging of the insulation between the sensing lines 25, 26.

With an embodiment schematically shown in FIG. 7, more than two sensing lines 25, 26 are provided. Thus, with the embodiment according to FIG. 7, for example, a sensing line 25, 26 is arranged in each intermediate space Z between the central, first cooling line 23 and the second cooling lines 24 grouped around it, along with the load lines 22. Thereby, the sensing lines 25, 26 are alternately acted upon with different potentials; for example, each sensing line 25 is at a measuring potential, and each sensing line 26 is at a ground potential. Thus, adjacent sensing lines 25, 26 are at different potentials, such that a potential difference arises between adjacent sensing lines 25, 26. If the electrical insulation between adjacent sensing lines 25, 26 is bridged locally, a current flow arises, which can be evaluated in order to detect a coolant leak within the cable sleeve 20.

By using more than two sensing lines 25, 26, a spatially close detection of a coolant leak within the cable sleeve 20 is possible.

The idea behind the invention is not limited to the embodiments described above, but can, in principle, also be realized in a completely different manner.

For example, the arrangement of load lines and cooling lines in a cable sleeve may be designed differently from the embodiments shown here. For example, only two load lines may be present in one cable sleeve.

The sensing lines are not electrically insulated, at least in sections. Preferably, the sensing lines are not electrically insulated along their entire length. However, this is not mandatory. An electrically-insulating sheath can thus also be provided in sections on the sensing lines, such that the sensing lines are exposed only in sections.

The electrical conductors of the sensing lines are, for example, provided with a metallic surface coating that makes the sensing lines insusceptible to corrosion.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMBERS

1 Charging station

10 Control device

2 Charging cable

20 Cable sleeve

200, 201 End

21 Shield line

22 Load line

220 Line core

221 Sheath

23, 24 Cooling line

25, 26 Sensing line

27 Signal line

28 Filling element

3 Charging plug

30 Housing

300, 301 Plug-in section

4 Vehicle

40 Charging socket

I Current

K Coolant

L Longitudinal direction

V Measuring potential (voltage)

Z Intermediate space

1: A cable for transferring an electric current, comprising:
a cable sleeve;
at least one electrical load line, extending into the cable sleeve, configured to conduct the electric current;
at least one cooling line, extending into the cable sleeve, configured to conduct a coolant; and
at least one electrically-conductive sensing line, which extends into the cable sleeve and, at least in sections, is not electrically insulated, configured to detect a measurement signal indicating a change in an electrical conductivity in the cable sleeve.

2: The cable according to claim 1, wherein the cable has a first sensing line extending into the cable sleeve and a second sensing line, extending into the cable sleeve, at a distance from the first sensing line.

3: The cable according to claim 2, wherein the first sensing line and the second sensing line are not electrically connected to each other in the cable sleeve.

4: The cable according to claim 1, wherein the cable has a central, first cooling line around which at least one second cooling line and the at least one electrical load line are grouped.

5: The cable according to claim 4, wherein the at least one sensing line extends into an intermediate space between the central, first cooling line and the at least one second cooling line or the at least one electrical load line.

6: The cable according to claim 1, wherein the at least one sensing line is connected to a control device that is configured to apply a measuring potential to the at least one sensing line, in order to detect the measurement signal indicating the change in the electrical conductivity in the cable sleeve.

7: The cable according to claim 6, wherein the control device is configured to switch off a current flowing over the at least one load line if the change in the electrical conductivity is detected in the cable sleeve.

8: The cable according to claim 1, wherein the cable is connected, at a first end, to a connector part and, at a second end turned away from the first end, to a charging station for charging an electric vehicle.
